(19) United States
(12) Patent Application Publication
(10) Pub. No.: US 2026/0121625 A1
(43) Pub. Date: Apr. 30, 2026

(54) PHASE SPLIT CIRCUIT GENERATING COMPLEMENTARY CLOCK SIGNALS AND MEMORY DEVICE INCLUDING THE SAME

(71) Applicant: Samsung Electronics Co., Ltd., Suwon-si (KR)

(72) Inventors: Daehyun KWON, Suwon-si (KR); Yongdeok AHN, Suwon-si (KR)

(73) Assignee: Samsung Electronics Co., Ltd., Suwon-si (KR)

(21) Appl. No.: 19/003,386

(22) Filed: Dec. 27, 2024

(30) Foreign Application Priority Data
Jun. 18, 2024 (KR) 10-2024-0078588

(51) Int. Cl. H03K 5/151; G11C 7/10; G11C 7/22; H03K 5/00; H03K 5/134

(52) U.S. Cl. CPC H03K 5/151; G11C 7/10; G11C 7/222; H03K 5/134; H03K 2005/00195

(57) ABSTRACT

A memory device, comprising a phase split circuit configured to generate a first clock signal and a second clock signal used in an input/output circuit. The phase split circuit including, a first delay path configured to output a first delay signal; a second delay path configured to output a second delay signal; a third delay path configured to output a third delay signal; and a fourth delay path configured to output a fourth delay signal. The phase split circuit also includes: a first output terminal configured to phase-interpolate the first delay signal and the second delay signal to output the first clock signal; and a second output terminal configured to combine the third delay signal and the fourth delay signal to output the second clock signal complementary to the first clock signal.

### CROSS-REFERENCE TO RELATED APPLICATION

This application claims priority under 35 U.S.C. § 119 to Korean Patent Application No. 10-2024-0078588 filed on Jun. 18, 2024, in the Korean Intellectual Property Office, the contents of which is hereby incorporated by reference in its entirety.

### BACKGROUND

### 1. Field

Example embodiments of the present inventive concepts described herein relate to a semiconductor memory device, and more particularly, relate to a phase split circuit for generating complementary clock signals and/or a memory device including the same.

### 2. Description of Related Art

A semiconductor memory may be mainly classified as a volatile memory or a non-volatile memory. Read and write speeds of the volatile memory (for example, a DRAM or an SRAM) are fast, but the data stored in the volatile memory disappear when power is turned off. In contrast, the non-volatile memory may retain data even when the power is turned off. Therefore, the non-volatile memory may be used to store contents that must be or are advantageous to be preserved regardless of whether power is supplied or not.

A representative example of a volatile memory device is a DRAM. A memory cell of a volatile memory device may include a single N-type transistor, serving as a switch, and a single capacitor storing electric charges DATA. Binary information “1” or “0” may correspond to the presence or absence of the electric charges stored in the capacitor in the memory cell, for example, whether a terminal voltage of a cell capacitor is high or low. The memory cell may be connected to a wordline and a bitline. The bitline may be connected to a sense amplifier. The sense amplifier may sense data, stored in the memory cell, through the bitline based on a voltage applied to the wordline.

The volatile memory device may use various clock signals to sense data stored in a memory cell and then transmit or send the data to a memory controller. In order to generate the various clock signals, the volatile memory device may include a phase split circuit which generates two complementary clock signals based on a reference clock signal. However, the two complementary clock signals may have different process variations due to transistors included in the phase split circuit. When the process variations of the various clock signals are different, the reliability of data output from the volatile memory device may be reduced or deteriorated.

### SUMMARY

Some example embodiments of the present inventive concepts provide a phase split circuit that generates complementary clock signals having uniform process variations.

Some example embodiments of the present inventive concepts provide a memory device which performs a stable data read operation based on complementary clock signals having uniform process variations.

According to some example embodiments, a memory device comprising: a memory cell array including a plurality of memory cells; an input/output circuit configured to input or output data to or from the plurality of memory cells; and a phase split circuit configured to generate a first clock signal and a second clock signal used in the input/output circuit during an output operation of the data. The phase split circuit including, a first delay path including an even number of inverters included in a first inverter group, the first delay path configured to output a first delay signal when a reference clock signal passes through the first inverter group; a second delay path including an even number of inverters included in a second inverter group, the second delay path configured to output a second delay signal when the reference clock signal passes through the second inverter group; a first output terminal configured to phase-interpolate the first delay signal and the second delay signal to output the first clock signal; a third delay path including an odd number of inverters included in a third inverter group and at least one buffer, the third delay path configured to output a third delay signal when the reference clock signal passes through the third inverter group and the at least one buffer; a fourth delay path including an odd number of inverters included in a fourth inverter group, the fourth delay path configured to output a fourth delay signal when the reference clock signal passes through the fourth inverter group; and a second output terminal configured to combine the third delay signal and the fourth delay signal to output the second clock signal complementary to the first clock signal.

According to some example embodiments, a phase split circuit comprising: a first delay path including an even number of inverters included in a first inverter group, the first delay path configured to output a first delay signal when a reference clock signal passes through the first inverter group; a second delay path including an even number of inverters included in a second inverter group, the second delay path configured to output a second delay signal when the reference clock signal passes through the second inverter group; a first output terminal configured to phase-interpolate the first delay signal and the second delay signal to output a first clock signal having a same phase as the reference clock signal; a third delay path including an odd number of inverters included in a third inverter group and at least one buffer, the third delay path configured to output a third delay signal when the reference clock signal passes through the third inverter group and the at least one buffer; a fourth delay path including an odd number of inverters included in a fourth inverter group, the fourth delay path configured to output a fourth delay signal when the reference clock signal passes through the fourth inverter group; and a second output terminal configured to combine the third delay signal and the fourth delay signal to output a second clock signal complementary to the first clock signal.

According to some example embodiments, a phase split circuit comprising: a first delay path including an even number of inverters connected in series between an input terminal and a first output terminal; a second delay path including an even number of inverters connected in series between the input terminal and the first output terminal, the second delay path configured to be connected in parallel to the first delay path and the first output terminal; a third delay path including one inverter and at least one buffer connected in series between the input terminal and a second output terminal; and a fourth delay path including an odd number of inverters connected in series between the input terminal and the second output terminal.

### BRIEF DESCRIPTION OF THE DRAWINGS

The above and other objects and features of the present inventive concepts will become apparent by describing in detail some embodiments thereof with reference to the accompanying drawings.

FIG. 1 is a block diagram illustrating a memory system according to some example embodiments.

FIG. 2 is a block diagram illustrating a memory device of FIG. 1 according to some example embodiments.

FIG. 3 is a diagram illustrating an example of the phase split circuit of FIG. 2 according to some example embodiments.

FIG. 4 is a diagram illustrating a process of generating a rising edge of a first clock signal in the phase split circuit of FIG. 3 according to some example embodiments.

FIG. 5 is a diagram illustrating a process of generating a falling edge of a first clock signal in the phase split circuit of FIG. 3 according to some example embodiments.

FIG. 6 is a diagram illustrating a process of generating a rising edge of a second clock signal in the phase split circuit of FIG. 3 according to some example embodiments.

FIG. 7 is a diagram illustrating a process of generating a falling edge of a second clock signal in the phase split circuit of FIG. 3 according to some example embodiments.

FIG. 8 is a timing diagram illustrating an effect of improving a process variation of the phase split circuit of FIG. 3 according to some example embodiments.

FIG. 9 is a timing diagram illustrating an example of an effect of improving a duty variation of a second clock signal in the phase split circuit of FIG. 3 according to some example embodiments.

FIG. 10 is a timing diagram illustrating an example of an effect of improving a duty variation of a second clock signal in the phase split circuit of FIG. 3 according to some example embodiments.

FIG. 11 is a diagram illustrating an example of the phase split circuit of FIG. 2 according to some example embodiments.

FIG. 12 is a drawing illustrating an example of the phase split circuit of FIG. 2 according to some example embodiments.

FIG. 13 is a drawing illustrating an example of the phase split circuit of FIG. 2 according to some example embodiments.

FIG. 14 is a drawing illustrating an example of the phase split circuit of FIG. 2 according to some example embodiments.

FIG. 15 is a drawing illustrating an example of the phase split circuit of FIG. 2 according to some example embodiments.

FIG. 16 is a drawing illustrating an example of the phase split circuit of FIG. 2 according to some example embodiments.

FIG. 17 is a drawing illustrating an example of the phase split circuit of FIG. 2 according to some example embodiments.

### DETAILED DESCRIPTION

Below, some example embodiments of the present inventive concepts will be described in detail and clearly to such an extent that an ordinary one in the art easily implements the present inventive concepts.

Below, a DRAM will be used as an example for illustrating features and functions of the present inventive concepts. However, other features and performances may be easily understood from information disclosed herein by a person of ordinary skill in the art. The present inventive concepts may be implemented by other example embodiments or applied thereto. Further, the detailed description may be modified or changed according to viewpoints and applications without escaping from the scope, spirit, and other objects of the present inventive concepts.

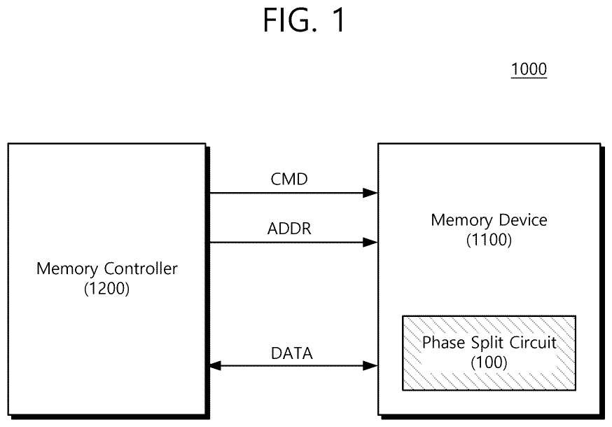

FIG. 1 is a block diagram illustrating a memory system according to some example embodiments. Referring to FIG. 1, a memory system 1000 may include a memory device 1100 and a memory controller 1200.

According to some example embodiments, the memory device 1100 may output data DATA, requested to be read by the memory controller 1200, to the memory controller 1200 or may store data DATA, requested to be written by the memory controller 1200, in a memory cell of the memory device 1100. The memory device 1100 may input and output data DATA based on a command CMD and an address ADDR. The memory device 1100 may include memory banks.

The memory device 1100 may be a volatile memory device such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. Alternatively, in some example embodiments, the memory device 1200 may be implemented as a nonvolatile memory device such as a resistive RAM (RRAM), a phase change memory (PRAM), a magnetoresistive memory (MRAM), a ferroelectric memory (FRAM), a spin-transfer torque RAM (STT-RAM), or the like. In the present specification, some example embodiments, and the advantages of the present inventive concepts have been described with respect to a DRAM, but example embodiments are not limited thereto.

According to some example embodiments, the memory banks may include a memory cell array divided in units of banks, a row decoder, a column decoder, a sense amplifier, a write driver, or the like. The memory banks may store data DATA, requested to be written in the memory device 1100, through the write driver and may read data DATA, requested to be read, using the sense amplifier. The memory banks may further include a component for a refresh operation of storing and maintaining data in the cell array, or select circuits based on an address.

According to some example embodiments, the memory controller 1200 may perform an access operation of writing data to the memory device 1100 or reading data stored in the memory device 1100. For example, the memory controller 1200 may generate a command CMD and an address ADDR for writing data to the memory device 1100 or reading data stored in the memory device 1100. The memory controller 1200 may include at least one of a control circuit controlling the memory device 1100, a system-on-chip (SoC) such as an application processor (AP), a central processing unit (CPU), a digital signal processor (DSP), and a graphics processing unit (GPU).

According to some example embodiments, the memory controller 1200 may provide various signals to the memory device 1100 to control an overall operation of the memory device 1100. For example, the memory controller 1200 may control memory access operations of the memory device 1100 such as a read operation and a write operation. The memory controller 1200 may provide the command CMD and the address ADDR to the memory device 1100 to write data DATA in the memory device 1100 or to read data DATA from the memory device 1100.

According to some example embodiments, the memory controller 1200 may generate various types of commands CMD to control the memory device 1100. For example, the memory controller 1200 may generate a bank request corresponding to a bank operation of changing a state of a memory bank, among memory banks, to read or write data DATA.

In some example embodiments, the bank request may include an active request for changing a state of a memory bank, among the memory banks, to an active state. The memory device 1100 may activate a row included in the memory bank, for example, a wordline, in response to the active request. The bank request may include a precharge request for changing the memory banks from an active state to a standby state after reading or writing of data DATA is completed.

In some example embodiments, the memory controller 1200 may generate an input/output (I/O) request (for example, a column address strobe (CAS) request) for the memory device 1100 to perform a read operation or a write operation of data DATA. For example, the I/O request may include a read request for reading data DATA from activated memory banks. The I/O request may include a write request for writing data DATA in the activated memory banks.

Furthermore, in some example embodiments, the memory controller 1200 may generate a refresh command to control a refresh operation on the memory banks. However, example embodiments are not limited thereto, and the types of commands CMD described herein are merely exemplary, and other types of commands CMD may be present. According to some example embodiments, the memory controller 1200 may include, may be included in, and/or may be implemented by one or more instances of processing circuitry. For example, the processing circuitry may include a non-transitory computer readable storage device (e.g., a memory) storing a program of instructions, and a processor configured to execute the program of instructions to implement the functionality and/or methods performed by the memory controller 1200.

According to some example embodiments, the memory device 1100 may include a phase split circuit 100. For example, the memory device 1100 may use clock signals having various phases during a read operation of data DATA. The phase split circuit 100 may generate two clock signals which are complementary to each other based on a reference clock signal. The memory device 1100 may generate the clock signals used during the read operation of data DATA based on the two clock signals generated by the phase split circuit 100.

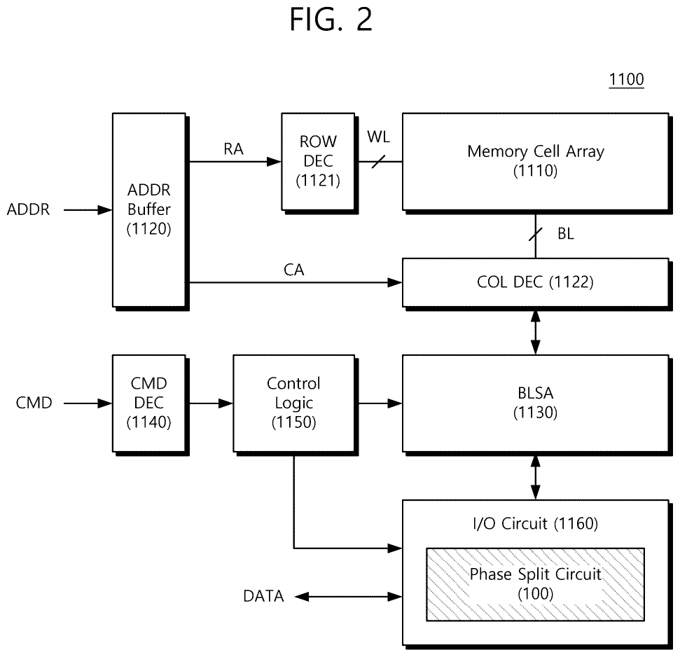

FIG. 2 is a block diagram illustrating a memory device of FIG. 1 according to some example embodiments. Referring to FIG. 2, the memory device 1100 may include a memory cell array 1110, an address buffer 1120, a row decoder 1121, a column decoder 1122, a bitline sense amplifier 1130, a command decoder 1140, control logic 1150, and an input/output circuit 1160. In addition, in some example embodiments, the memory device 1100 may include a phase split circuit 100.

According to some example embodiments, the memory cell array 1110 may include a plurality of memory cells arranged in a matrix of rows and columns. For example, the memory cell array 1110 may include a plurality of wordlines WL and a plurality of bitlines BL connected to memory cells. The plurality of wordlines WL may be connected to rows of the memory cells, and the plurality of bitlines BL may be connected to columns of the memory cells.

According to some example embodiments, the address buffer 1120 may receive an address ADDR from the memory controller 1200 of FIG. 1. For example, the address ADDR may include a row address RA addressing a row of the memory cell array 1110 and a column address CA addressing a column of the memory cell array 1110. The address buffer 1120 may transmit or send the row address RA to the row decoder 1121 and may transmit or send the column address CA to the column decoder 1122.

According to some example embodiments, the row decoder 1121 may select one of the plurality of wordlines WL connected to the memory cell array 1110. The row decoder 1121 may decode the row address RA, received from the address buffer 1120, to select a single wordline corresponding to the row address RA and may activate the selected wordline.

According to some example embodiments, the column decoder 1122 may select a predetermined bitline from among the plurality of bitlines BL of the memory cell array 1110. The column decoder 1122 may decode the column address CA, received from the address buffer 1120, to select the predetermined bitline BL corresponding to the column address CA.

According to some example embodiments, the bitline sense amplifier 1130 may be connected to the bitlines BL of the memory cell array 1110. For example, the bitline sense amplifier 1130 may sense a change in voltage of a selected bitline, among the plurality of bitlines BL, and may amplify and output the change in voltage.

According to some example embodiments, the command decoder 1140 may decode a write enable signal /WE, a row address strobe signal /RAS, a column address strobe signal /CAS, and a chip select signal /CS received from the memory controller 1200 such that control signals corresponding to the command CMD are generated in the control logic 1150. The command CMD may include an active request, a read request, a write request, or a precharge request.

The control logic 1150 may control an overall operation of the bitline sense amplifier 1130 through the control signals corresponding to the command CMD. The control logic 1150 may generate control signals such that the bitline sense amplifier 1130 operates as a single-ended sense amplifier. Additionally, in some example embodiments, the control logic 1150 may control an overall operation of the memory device 1100.

According to some example embodiments, the input/output circuit 1160 may output data DATA to the memory controller 1200 through data pad based on a sensed and amplified voltage from the bitline sense amplifier 1130. For example, the input/output circuit 1160 may include an input buffer or an output buffer. The input buffer or the output buffer may be connected to the data pad. The input/output circuit 1160 may perform a serialization operation or a deserialization operation of data DATA. In some example embodiments, each of the address buffer 1120, row decoder 1121, column decoder 1122, bitline sensor amplifier 1130, command decoder 1140, control logic, and input/output circuit 1160, may include, may be included in, and/or may be implemented by one or more instances of processing circuitry such as hardware including logic circuits; a hardware/software combination such as a processor executing software; or a combination thereof. For example, the processing circuitry may include a non-transitory computer readable storage device (e.g., a memory) storing a program of instructions, and a processor configured to execute the program of instructions to implement the functionality and/or methods performed by some or all of the the address buffer 1120, row decoder 1121, column decoder 1122, bitline sensor amplifier 1130, command decoder 1140, control logic, and input/output circuit 1160.

According to some example embodiments, the phase split circuit 100 may generate two clock signals which are complementary to each other based on a reference clock signal. For example, the input/output circuit 1160 may use clock signals having various phases during a read operation of data DATA. The input/output circuit 1160 may receive the reference clock signal from an outside device (for example, the memory controller 1200) or generate the reference clock signal internally. The input/output circuit 1160 may generate two clock signals which are complementary to each other based on the reference clock signal through the phase split circuit 100. The input/output circuit 1160 may generate clock signals having various phases which are used during a read operation of data DATA based on the two clock signals generated by the phase split circuit 100.

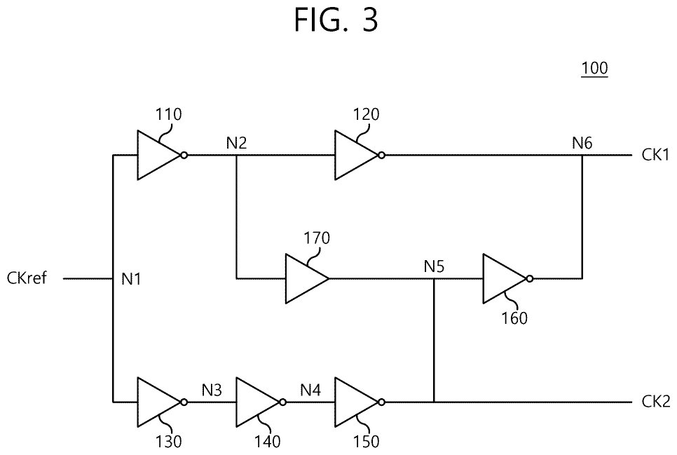

FIG. 3 is a diagram illustrating an example of the phase split circuit of FIG. 2 according to some example embodiments. Referring to FIG. 3, the phase split circuit 100 may receive a reference clock signal CKref and output a first clock signal CK1 and a second clock signal CK2. The first clock signal CK1 may have the same phase as the reference clock signal CKref. The second clock signal CK2 may have a phase complementary to the reference clock signal CKref (or the first clock signal CK1).

According to some example embodiments, the phase split circuit 100 may include a plurality of inverters and at least one buffer. For example, the phase split circuit 100 may include a first inverter 110 to a sixth inverter 160. The phase split circuit 100 may include a buffer 170.

According to some example embodiments, the plurality of inverters 110, 120, 130, 140, 150, and 160 may be connected between one input node and two output nodes. For example, the first inverter 110 may be connected between a first node N1 and a second node N2. The first node N1 may be an input node. The second inverter 120 may be connected between the second node N2 and a sixth node N6. The sixth node N6 may be a first output node. The third inverter 130 may be connected between the first node N1 and a third node N3. The fourth inverter 140 may be connected between the third node N3 and a fourth node N4. The fifth inverter 150 may be connected between the fourth node N4 and a fifth node N5. The fifth node N5 may be a second output node. The sixth inverter 160 may be connected between the fifth node N5 and the sixth node N6.

According to some example embodiments, the reference clock signal CKref may be input to the input node (or the first node N1). The first clock signal CK1 may be output to the first output node (or the sixth node N6). The second clock signal CK2 may be output to the second output node (or the fifth node N5).

According to some example embodiments, the phase split circuit 100 may generate the first clock signal CK1 having the same phase as the reference clock signal CKref through an even number of inverters. For example, the reference clock signal CKref may be output as a first delay signal through the first inverter 110 and the second inverter 120. In addition, in some example embodiments, the reference clock signal CKref may be output as a second delay signal through the third inverter 130, the fourth inverter 140, the fifth inverter 150 and the sixth inverter 160.

According to some example embodiments, the phase split circuit 100 may perform phase interpolation through an even path in which a signal is transmitted or sent through an even number of inverters. For example, the first delay signal and the second delay signal may be phase-interpolated at the first output node (or the sixth node N6) and an interpolated signal may be output as the first clock signal CK1. In the even path, process variation by the inverters may be improved through the phase interpolation. Accordingly, duty variation of the first clock signal CK1 may be improved.

According to some example embodiments, the phase split circuit 100 may generate the second clock signal CK2 whose phase is complementary to the reference clock signal CKref through an odd number of inverters. For example, the reference clock signal CKref may be inverted through the first inverter 110 and output to the second node N2. The output signal of the first inverter 110 may be output as a third delay signal while a phase of the output signal of the first inverter 110 is maintained through the buffer 170. In addition, in some example embodiments, the reference clock signal CKref may be inverted through the third inverter 130, the fourth inverter 140 and the fifth inverter 150. The output signal of the fifth inverter 150 may be output as a fourth delay signal.

According to some example embodiments, the phase split circuit 100 may perform a duty compensation operation through an odd path in which a signal is transmitted or sent through an odd number of inverters. For example, the third delay signal and the fourth delay signal may be merged at the second output node (or the fifth node N5). The buffer 170 may offset a process variation in a reverse direction in response to the fourth inverter 140. Accordingly, a duty variation of the second clock signal CK2 may be improved.

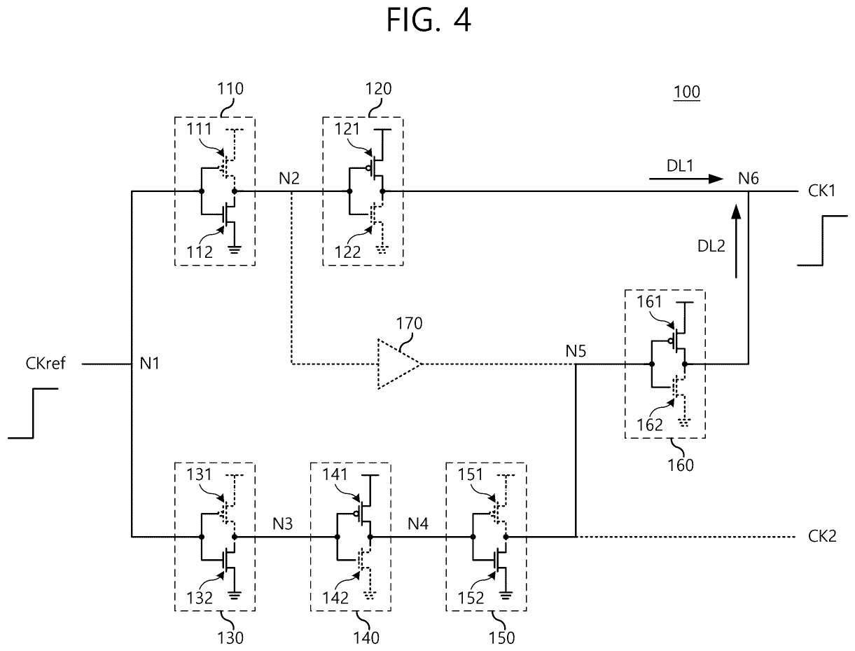

FIG. 4 is a diagram illustrating a process of generating a rising edge of a first clock signal in the phase split circuit of FIG. 3 according to some example embodiments. Referring to FIGS. 3 and 4, each of the plurality of inverters 110, 120, 130, 140, 150, and 160 included in the phase split circuit 100 may include a P-type transistor and an N-type transistor. The reference clock signal CKref may be input to the input node (or the first node N1) and may be output to the first output node (or the sixth node N6) along a first delay path DL1 and a second delay path DL2. The first clock signal CK1 may have the same phase as the reference clock signal CKref. FIG. 4 may illustrate operations of the plurality of inverters when the reference clock signal CKref is a rising edge.

According to some example embodiments, in the first delay path DL1, the reference clock signal CKref may be transmitted or sent through the first inverter 110 and the second inverter 120. For example, the first inverter 110 may include a first P-type transistor 111 and a first N-type transistor 112. The second inverter 120 may include a second P-type transistor 121 and a second N-type transistor 122.

For example, the first P-type transistor 111 may include a gate connected to the first node N1, a source connected to a power supply voltage terminal, and a drain connected to the second node N2. The first N-type transistor 112 may include a gate connected to the first node N1, a source connected to a ground terminal, and a drain connected to the second node N2.

The second P-type transistor 121 may include a gate connected to the second node N2, a source connected to the power supply voltage terminal, and a drain connected to the sixth node N6. The second N-type transistor 122 may include a gate connected to the second node N2, a source connected to the ground terminal, and a drain connected to the sixth node N6.

According to some example embodiments, in the first inverter 110, the first P-type transistor 111 may be turned off and the first N-type transistor 112 may be turned on by a high level of the reference clock signal CKref. Accordingly, the second node N2 may be at a low level.

In the second inverter 120, when the second node N2 is at a low level, the second P-type transistor 121 may be turned on and the second N-type transistor 122 may be turned off. Accordingly, a high level of a first delay signal may be transmitted or sent to the first output node (or the sixth node N6) through the first delay path DL1.

According to some example embodiments, in the second delay path DL2, the reference clock signal CKref may be transmitted or sent through the third inverter 130, the fourth inverter 140, the fifth inverter 150 and the sixth inverter 160. For example, the third inverter 130 may include a third P-type transistor 131 and a third N-type transistor 132. The fourth inverter 140 may include a fourth P-type transistor 141 and a fourth N-type transistor 142. The fifth inverter 150 may include a fifth P-type transistor 151 and a fifth N-type transistor 152. The sixth inverter 160 may include a sixth P-type transistor 161 and a sixth N-type transistor 162.

For example, the third P-type transistor 131 may include a gate connected to the first node N1, a source connected to the power supply voltage terminal, and a drain connected to the third node N3. The third N-type transistor 132 may include a gate connected to the first node N1, a source connected to the ground terminal, and a drain connected to the third node N3.

The fourth P-type transistor 141 may include a gate connected to the third node N3, a source connected to the power supply voltage terminal, and a drain connected to the fourth node N4. The fourth N-type transistor 142 may include a gate connected to the third node N3, a source connected to the ground terminal, and a drain connected to the fourth node N4.

The fifth P-type transistor 151 may include a gate connected to the fourth node N4, a source connected to the power supply voltage terminal, and a drain connected to the fifth node N5. The fifth N-type transistor 152 may include a gate connected to the fourth node N4, a source connected to the ground terminal, and a drain connected to the fifth node N5.

The sixth P-type transistor 161 may include a gate connected to the fifth node N5, a source connected to the power supply voltage terminal, and a drain connected to the sixth node N6. The sixth N-type transistor 162 may include a gate connected to the fifth node N5, a source connected to the ground terminal, and a drain connected to the sixth node N6.

According to some example embodiments, in the third inverter 130, the third P-type transistor 131 may be turned off and the third N-type transistor 132 may be turned on by a high level of the reference clock signal CKref. Accordingly, the third node N3 may be at a low level.

In the fourth inverter 140, when the third node N3 is at a low level, the fourth P-type transistor 141 may be turned on and the fourth N-type transistor 142 may be turned off. Accordingly, the fourth node N4 may be at a high level.

In the fifth inverter 150, when the fourth node N4 is at a high level, the fifth P-type transistor 151 may be turned off and the fifth N-type transistor 152 may be turned on. Accordingly, the fifth node N5 may be at a low level.

In the sixth inverter 160, when the fifth node N5 is at a low level, the sixth P-type transistor 161 may be turned on and the sixth N-type transistor 162 may be turned off. Accordingly, a high level of a second delay signal may be transmitted or sent to the first output node (or the sixth node N6) through the second delay path DL2.

According to some example embodiments, the first delay signal and the second delay signal may be phase-interpolated at the first output node (or the sixth node N6) and an interpolated signal may be output as the first clock signal CK1. A process variation may be caused by a difference in characteristics between a P-type transistor and an N-type transistor. The first clock signal CK1 may be generated through the first delay path DL1 and the second delay path DL2, which are the even paths.

As described above, in some example embodiments, in the even paths, the number of P-type transistors or the number of N-type transistors included in the inverters may be matched with each other, so that a difference in a process variation may be offset. Accordingly, the process variation by the inverters included in the even paths may be improved. In addition, in some example embodiments, the duty variation of the first clock signal CK1 may be improved.

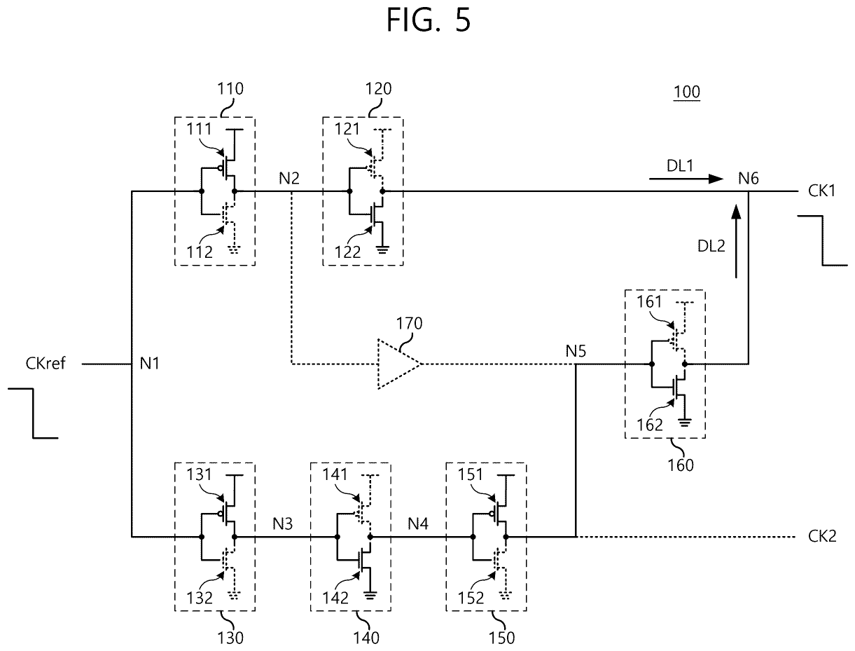

FIG. 5 is a diagram illustrating a process of generating a falling edge of a first clock signal in the phase split circuit of FIG. 3 according to some example embodiments. Referring to FIGS. 3 and 5, each of the plurality of inverters included in the phase split circuit 100 may include a P-type transistor and an N-type transistor. The reference clock signal CKref may be input to the input node (or the first node N1) and may be output to the first output node (or the sixth node N6) along the first delay path DL1 and the second delay path DL2. The first clock signal CK1 may have the same phase as the reference clock signal CKref. FIG. 5 may illustrate an operation of the plurality of inverters when the reference clock signal CKref is a falling edge.

According to some example embodiments, in the first delay path DL1, the reference clock signal CKref may be transmitted or sent through the first inverter 110 and the second inverter 120. For example, the first inverter 110 may include the first P-type transistor 111 and the first N-type transistor 112. The second inverter 120 may include the second P-type transistor 121 and the second N-type transistor 122.

In the first inverter 110, the first P-type transistor 111 may be turned on and the first N-type transistor 112 may be turned off by a low level of the reference clock signal CKref. Accordingly, the second node N2 may be at a high level.

In the second inverter 120, when the second node N2 is a high level, the second P-type transistor 121 may be turned off and the second N-type transistor 122 may be turned on. Accordingly, a low level of a first delay signal may be transmitted or sent to the first output node (or the sixth node N6) through the first delay path DL1.

According to some example embodiments, in the second delay path DL2, the reference clock signal CKref may be transmitted or sent through the third inverter 130, the fourth inverter 140, the fifth inverter 150 and the sixth inverter 160. For example, the third inverter 130 may include the third P-type transistor 131 and the third N-type transistor 132. The fourth inverter 140 may include the fourth P-type transistor 141 and the fourth N-type transistor 142. The fifth inverter 150 may include the fifth P-type transistor 151 and the fifth N-type transistor 152. The sixth inverter 160 may include the sixth P-type transistor 161 and the sixth N-type transistor 162.

In the third inverter 130, the third P-type transistor 131 may be turned on and the third N-type transistor 132 may be turned off by a low level of the reference clock signal CKref. Accordingly, the third node N3 may be at a high level.

In the fourth inverter 140, when the third node N3 is a high level, the fourth P-type transistor 141 may be turned off and the fourth N-type transistor 142 may be turned on. Accordingly, the fourth node N4 may be at a low level.

In the fifth inverter 150, when the fourth node N4 is at a low level, the fifth P-type transistor 151 may be turned on and the fifth N-type transistor 152 may be turned off. Accordingly, the fifth node N5 may be at a high level.

In the sixth inverter 160, when the fifth node N5 is at a high level, the sixth P-type transistor 161 may be turned off and the sixth N-type transistor 162 may be turned on. Accordingly, a low level of a second delay signal may be transmitted or sent to the first output node (or the sixth node N6) through the second delay path DL2.

According to some example embodiments, the first delay signal and the second delay signal may be phase-interpolated at the first output node (or the sixth node N6) and an interpolated signal may output as the first clock signal CK1. A process variation may be caused by the difference in characteristics between a P-type transistor and a N-type transistor. The first clock signal CK1 may be generated through the first delay path DL1 and the second delay path DL2, which are the even paths.

As described above, in some example embodiments, in the even path, the number of P-type transistors or the number of N-type transistors included in the inverters may be matched with each other, so that a difference in a process variation may be offset. Accordingly, the process variation by the inverters included in the even paths may be improved. In addition, in some example embodiments, the duty variation of the first clock signal CK1 may be improved.

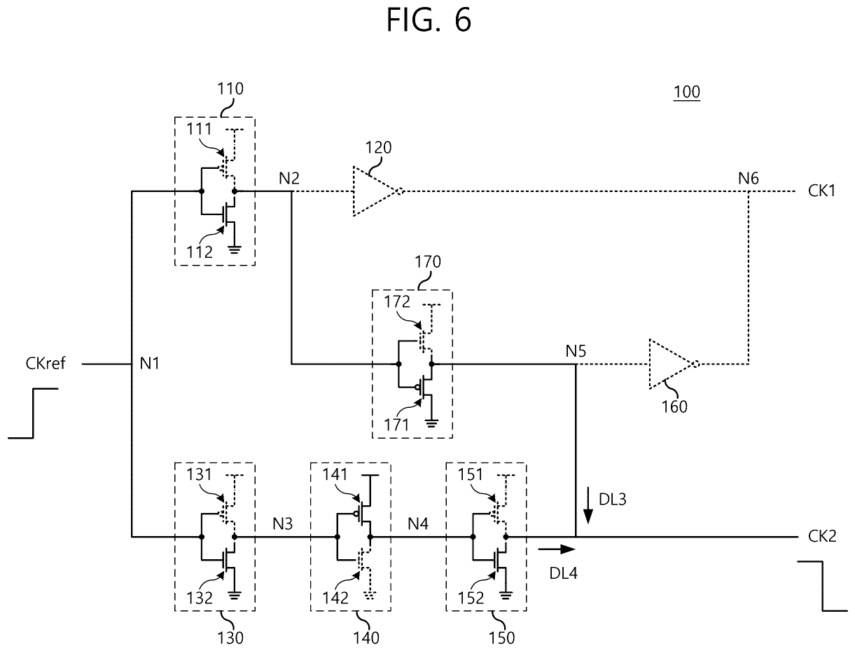

FIG. 6 is a diagram illustrating a process of generating a rising edge of a second clock signal in the phase split circuit of FIG. 3 according to some example embodiments. Referring to FIGS. 3 and 6, each of the plurality of inverters and the buffer included in the phase split circuit 100 may include a P-type transistor and an N-type transistor. The reference clock signal CKref may be input to the input node (or the first node N1) and may be output to the second output node (or the fifth node N5) along a third delay path DL3 and a fourth delay path DL4. The second clock signal CK2 may have a phase complementary to the reference clock signal CKref. FIG. 6 may illustrate, according to some example embodiments, an operation of the plurality of inverters and at least one buffer when the reference clock signal CKref is a rising edge.

According to some example embodiments, in the third delay path DL3, the reference clock signal CKref may be transmitted or sent through the first inverter 110 and the buffer 170. For example, the first inverter 110 may include the first P-type transistor 111 and the first N-type transistor 112. The buffer 170 may include a seventh P-type transistor 171 and a seventh N-type transistor 172.

As an example, the seventh P-type transistor 171 may include a gate connected to the second node N2, a source connected to the fifth node N5, and a drain connected to the ground terminal. The seventh N-type transistor 172 may include a gate connected to the second node N2, a source connected to the fifth node N5, and a drain connected to the power supply voltage terminal.

In the first inverter 110, the first P-type transistor 111 may be turned off and the first N-type transistor 112 may be turned on by a high level of the reference clock signal CKref. Accordingly, the second node N2 may be at a low level.

In the buffer 170, when the second node N2 is at a low level, the seventh P-type transistor 171 may be turned on and the seventh N-type transistor 172 may be turned off. Accordingly, a low level of the second node N2 may be identically transmitted or sent to the fifth node N5. Accordingly, a low level of a third delay signal may be transmitted or sent to the second output node (or the fifth node N5) through the third delay path DL3. The buffer 170 may offset an influence of the process variation of the fourth inverter 140.

According to some example embodiments, in the fourth delay path DL4, the reference clock signal CKref may be transmitted or sent through the third inverter 130, the fourth inverter 140, and the fifth inverter 150. For example, the third inverter 130 may include the third P-type transistor 131 and the third N-type transistor 132. The fourth inverter 140 may include the fourth P-type transistor 141 and the fourth N-type transistor 142. The fifth inverter 150 may include the fifth P-type transistor 151 and the fifth N-type transistor 152.

In the third inverter 130, the third P-type transistor 131 may be turned off and the third N-type transistor 132 may be turned on by a high level of the reference clock signal CKref. Accordingly, the third node N3 may be at a low level.

In the fourth inverter 140, when the third node N3 is at a low level, the fourth P-type transistor 141 may be turned on and the fourth N-type transistor 142 may be turned off. Accordingly, the fourth node N4 may be at a high level.

In the fifth inverter 150, when the fourth node N4 is at a high level, the fifth P-type transistor 151 may be turned off and the fifth N-type transistor 152 may be turned on. Accordingly, a high level of a fourth delay signal may be transmitted or sent to the second output node (or the fifth node N5) through the fourth delay path DL4.

According to some example embodiments, the third delay signal and the fourth delay signal may be combined at the second output node (or the fifth node N5) and a combined signal may be output as the second clock signal CK2. A process variation may be caused by the difference in characteristics between the P-type transistor and the N-type transistor. The second clock signal CK2 may be generated through the third delay path DL3 and the fourth delay path DL4, which are the odd paths.

As described above, in some example embodiments, in the odd paths, at least one buffer (for example, the buffer 170) included in the third delay path DL3 may offset a difference in the process variation corresponding to a portion of the inverters (for example, fourth inverter 140) included in the fourth delay path DL4. Accordingly, the process variation by the inverters included in the odd path may be improved. In addition, in some example embodiments, the duty variation of the second clock signal CK2 may be improved.

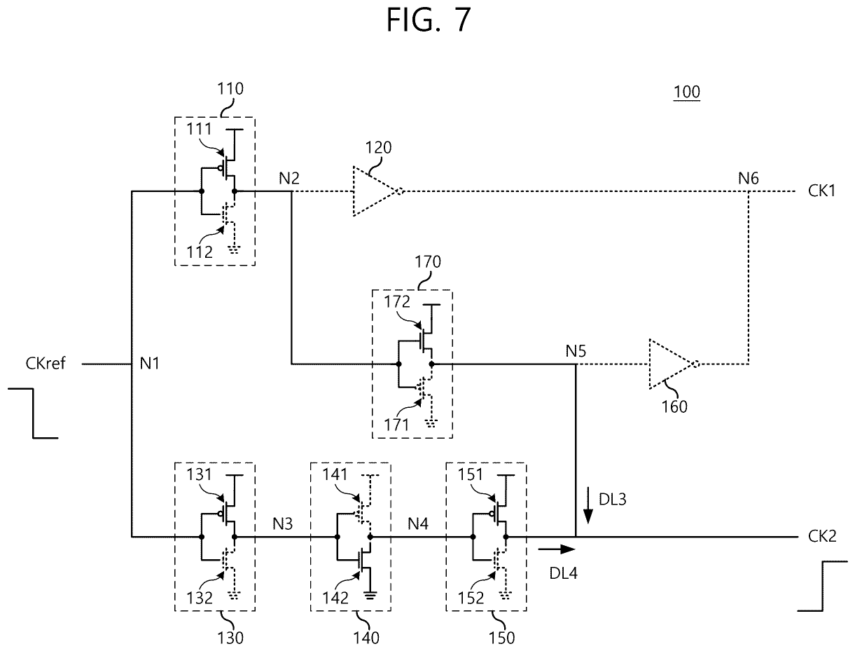

FIG. 7 is a diagram illustrating a process of generating a falling edge of a second clock signal in the phase split circuit of FIG. 3 according to some example embodiments. Referring to FIGS. 3 and 7, each of the plurality of inverters and the buffer included in the phase split circuit 100 may include the P-type transistor and the N-type transistor. The reference clock signal CKref may be input to the input node (or the first node N1) and may be output to the second output node (or the fifth node N5) along the third delay path DL3 and the fourth delay path DL4. The second clock signal CK2 may have a phase complementary to the reference clock signal CKref. FIG. 7 may illustrate, according to some example embodiments, an operation of the plurality of inverters and at least one buffer when the reference clock signal CKref is a falling edge.

According to some example embodiments, in the third delay path DL3, the reference clock signal CKref may be transmitted or sent through the first inverter 110 and the buffer 170. For example, the first inverter 110 may include the first P-type transistor 111 and the first N-type transistor 112. The buffer 170 may include the seventh P-type transistor 171 and the seventh N-type transistor 172.

In the first inverter 110, the first P-type transistor 111 may be turned on and the first N-type transistor 112 may be turned off by a low level of the reference clock signal CKref. Accordingly, the second node N2 may be at a high level.

In the buffer 170, when the second node N2 is at a high level, the seventh P-type transistor 171 may be turned off and the seventh N-type transistor 172 may be turned on. Accordingly, the high level of the second node N2 may be identically transmitted or sent to the fifth node N5. Accordingly, a high level of a third delay signal may be transmitted or sent to the second output node (or the fifth node N5) through the third delay path DL3. The buffer 170 may offset an effect of the process variation of the fourth inverter 140.

According to some example embodiments, in the fourth delay path DL4, the reference clock signal CKref may be transmitted or sent through the third inverter 130, the fourth inverter 140 and the fifth inverter 150. For example, the third inverter 130 may include the third P-type transistor 131 and the third N-type transistor 132. The fourth inverter 140 may include the fourth P-type transistor 141 and the fourth N-type transistor 142. The fifth inverter 150 may include the fifth P-type transistor 151 and the fifth N-type transistor 152.

In the third inverter 130, the third P-type transistor 131 may be turned on and the third N-type transistor 132 may be turned off by a low level of the reference clock signal CKref. Accordingly, the third node N3 may be at a high level.

In the fourth inverter 140, when the third node N3 is a high level, the fourth P-type transistor 141 may be turned off and the fourth N-type transistor 142 may be turned on. Accordingly, the fourth node N4 may be at a low level.

In the fifth inverter 150, when the fourth node N4 is a low level, the fifth P-type transistor 151 may be turned on and the fifth N-type transistor 152 may be turned off. Accordingly, a high level of a fourth delay signal may be transmitted or sent to the second output node (or the fifth node N5) through the fourth delay path DL4.

According to some example embodiments, the third delay signal and the fourth delay signal may be combined at the second output node (or the fifth node N5) and a combined signal may be output as the second clock signal CK2. A process variation may be caused by a difference in characteristics between the P-type transistor and the N-type transistor. The second clock signal CK2 may be generated through the third delay path DL3 and the fourth delay path DL4, which are the odd paths.

As described above, in some example embodiments, in the odd paths, at least one buffer (for example, the buffer 170) included in the third delay path DL3 may offset a difference in the process variation corresponding to a portion of the inverters (for example, fourth inverter 140) included in the fourth delay path DL4. Accordingly, the process variation by the inverters included in the odd paths may be improved. In addition, in some example embodiments, the duty variation of the second clock signal CK2 may be improved.

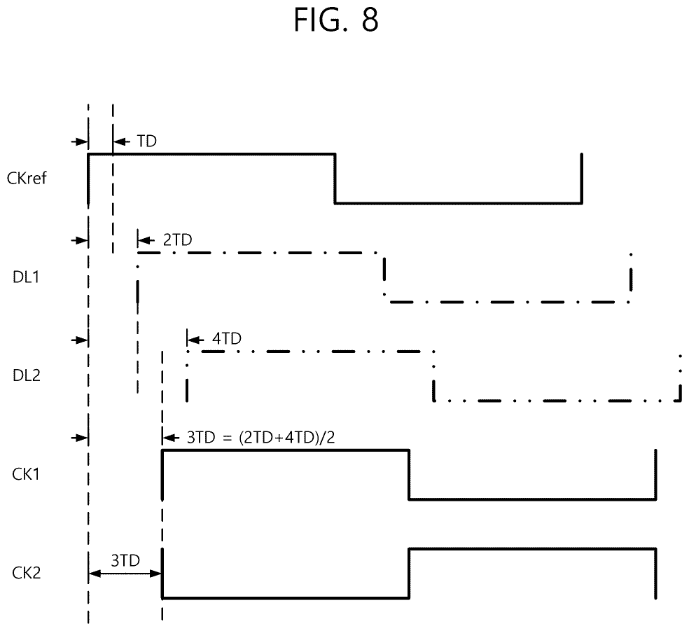

FIG. 8 is a timing diagram illustrating an effect of improving a process variation of the phase split circuit of FIG. 3 according to some example embodiments. Referring to FIGS. 3 to 8, the phase split circuit 100 may improve the process variations of the even paths and the odd paths through the phase interpolation of the even paths.

According to some example embodiments, the reference clock signal CKref may be delayed by a delay time TD when passing through one inverter. Accordingly, the first delay path DL1 includes two inverters, and the reference clock signal CKref passing through the first delay path DL1 may be delayed by twice the delay time 2TD. The second delay path DL2 includes four inverters, and the reference clock signal CKref passing through the second delay path DL2 may be delayed by four times the delay time 4TD. Therefore, a signal passing through the first delay path DL1 and a signal passing through the second delay path DL2 are phase-interpolated at the sixth node N6. The first clock signal CK1 may be delayed by a delay time 3TD three times greater than the reference clock signal CKref.

According to some example embodiments, the reference clock signal CKref may pass through three inverters via the fourth delay path DL4. Accordingly, the second clock signal CK2 may be delayed by a delay time 3TD three times greater than the reference clock signal CKref. In addition, in some example embodiments, the second clock signal CK2 may have a complementary phase to the reference clock signal CKref.

Therefore, the second clock signal CK2 may have a complementary phase to the first clock signal CK1 and have a same delay time from the reference clock signal CKref.

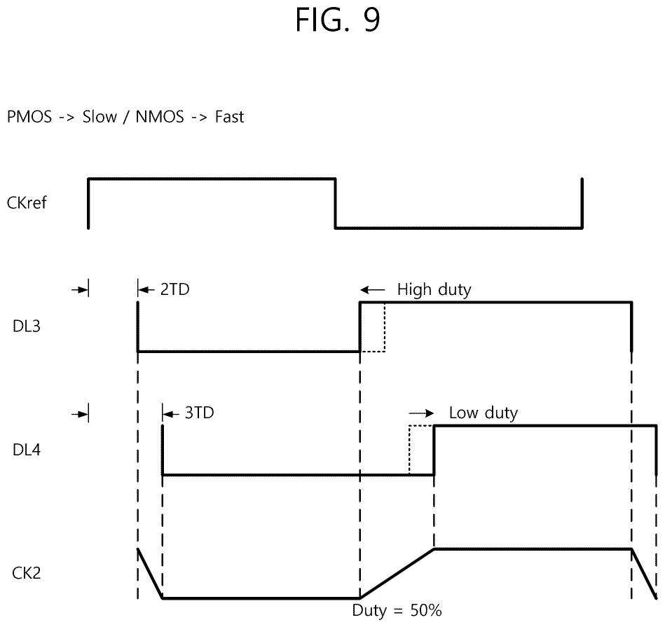

FIG. 9 is a timing diagram illustrating an example of an effect of improving a duty variation of a second clock signal in the phase split circuit of FIG. 3 according to some example embodiments. Referring to FIGS. 3, 6, 7 and 9, the P-type transistors included in the phase split circuit 100 may have a slow response speed, and the N-type transistors may have a fast response speed.

According to some example embodiments, in the third delay path DL3, the reference clock signal CKref may pass through one inverter 110 and one buffer 170. Accordingly, the clock signal passing through the third delay path DL3 may be delayed by twice the delay time 2TD of the reference clock signal CKref and inverted. The clock signal may have a high duty state in which a high level is longer than a low level in one cycle.

According to some example embodiments, in the fourth delay path DL4, the reference clock signal CKref may pass through three inverters 130, 140 and 150. Accordingly, the clock signal passing through the fourth delay path DL4 is delayed by the delay time 3TD three times than the reference clock signal CKref and inverted. The clock signal may have a low duty state in which a low level is longer than a high level in one cycle.

According to some example embodiments, the clock signal passing through the third delay path DL3 and the clock signal passing through the fourth delay path DL4 may be combined as the second clock signal CK2 at the fifth node N5. Therefore, the duty variation of the second clock signal CK2 may be improved.

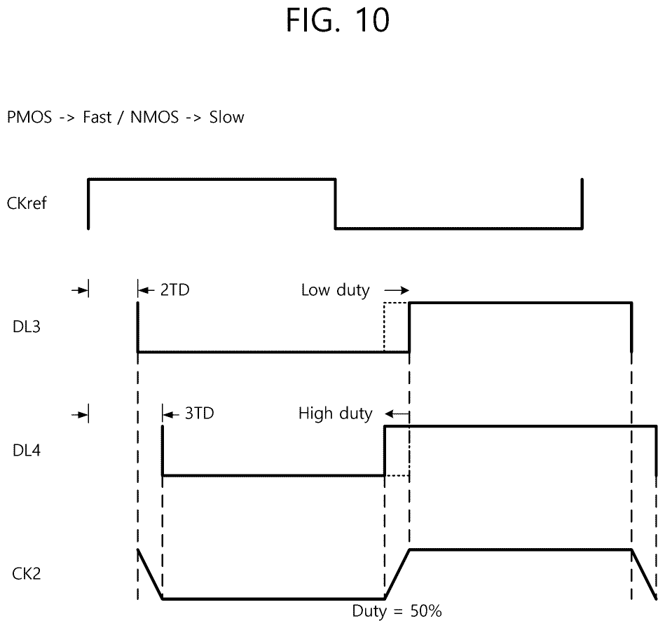

FIG. 10 is a timing diagram illustrating an example of an effect of improving a duty variation of a second clock signal in the phase split circuit of FIG. 3 according to some example embodiments. Referring to FIGS. 3, 6, 7, and 10, the P-type transistors included in the phase split circuit 100 may have a fast response speed, and the N-type transistors may have a slow response speed.

According to some example embodiments, in the third delay path DL3, the reference clock signal CKref may pass through one inverter 110 and one buffer 170. Accordingly, the clock signal passing through the third delay path DL3 may be inverted by being delayed by the delay time 2TD two times than the reference clock signal CKref and may have a low duty state.

According to some example embodiments, in the fourth delay path DL4, the reference clock signal CKref may pass through three inverters 130, 140 and 150. Accordingly, the clock signal passing through the fourth delay path DL4 may be inverted by being delayed by the delay time 3TD three times than the reference clock signal CKref and may have a high duty state.

According to some example embodiments, the clock signal passing through the third delay path DL3 and the clock signal passing through the fourth delay path DL4 may be combined as the second clock signal CK2 at the fifth node N5. Accordingly, the duty variation of the second clock signal CK2 may be improved.

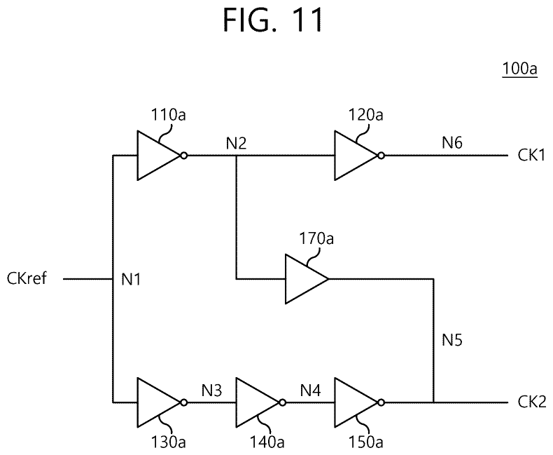

FIG. 11 is a diagram illustrating an example of the phase split circuit of FIG. 2 according to some example embodiments. Referring to FIG. 11, a phase split circuit 100a may receive a reference clock signal CKref and output a first clock signal CK1 and a second clock signal CK2. The first clock signal CK1 may have the same phase as the reference clock signal CKref. The second clock signal CK2 may have a complementary phase with the reference clock signal CKref (or the first clock signal CK1).

According to some example embodiments, a first inverter 110a may be connected between a first node N1 and a second node N2. The first node N1 may be an input node. A second inverter 120a may be connected between the second node N2 and a sixth node N6. The sixth node N6 may be a first output node. A third inverter 130a may be connected between the first node N1 and a third node N3. A fourth inverter 140a may be connected between the third node N3 and a fourth node N4. A fifth inverter 150a may be connected between the fourth node N4 and a fifth node N5. The fifth node N5 may be a second output node.

According to some example embodiments, the reference clock signal CKref may be input to the input node (or the first node N1). The first clock signal CK1 may be output to the first output node (or the sixth node N6). The second clock signal CK2 may be output to the second output node (or the fifth node N5).

According to some example embodiments, the phase split circuit 100a may output the first clock signal CK1 through an even path. For example, the even path may include a first delay path. The first delay path may include the first inverter 110a and the second inverter 120a.

According to some example embodiments, the phase split circuit 100a may output the second clock signal CK2 through odd paths. For example, the odd paths may include a second delay path and a third delay path. The second delay path may include the first inverter 110a and a buffer 170a. The third delay path may include the third to fifth inverters 130a, 140a and 150a.

According to some example embodiments, the phase split circuit 100a may perform a duty compensation operation through the odd paths. For example, a signal passing through the second delay path and a signal passing through the third delay path may be merged at the second output node (or the fifth node N5). The buffer 170 may offset the process variation in the reverse direction in response to the fourth inverter 140a. Accordingly, the duty variation of the second clock signal CK2 may be improved as described in FIGS. 9 and 10.

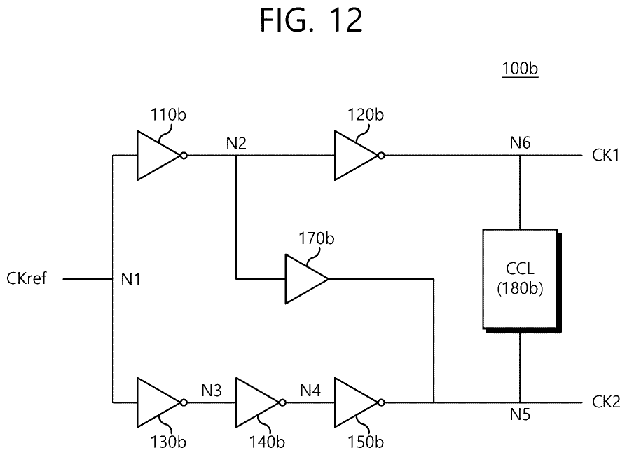

FIG. 12 is a drawing illustrating an example of the phase split circuit of FIG. 2 according to some example embodiments. Referring to FIG. 12, a phase split circuit 100b may receive a reference clock signal CKref and output a first clock signal CK1 and a second clock signal CK2. The first clock signal CK1 may have the same phase as the reference clock signal CKref. The second clock signal CK2 may have a complementary phase with the reference clock signal CKref (or the first clock signal CK1).

According to some example embodiments, the phase split circuit 100b may include a cross-coupled latch 180b. The phase split circuit 100b may be identical to the phase split circuit 100a of FIG. 11 except for the cross-coupled latch 180b. For example, the cross-coupled latch 180b may be connected between the fifth node N5 and the sixth node N6. The cross-coupled latch 180b may store values of the first clock signal CK1 and the second clock signal CK2.

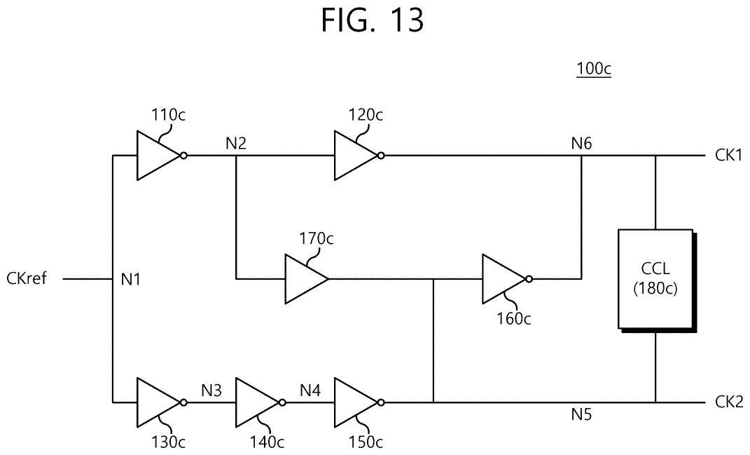

FIG. 13 is a drawing illustrating an example of the phase split circuit of FIG. 2 according to some example embodiments. Referring to FIG. 13, a phase split circuit 100c may receive a reference clock signal CKref and output a first clock signal CK1 and a second clock signal CK2. The first clock signal CK1 may have the same phase as the reference clock signal CKref. The second clock signal CK2 may have a complementary phase with the reference clock signal CKref (or the first clock signal CK1).

According to some example embodiments, the phase split circuit 100c may include a cross-coupled latch 180c. The phase split circuit 100c may be identical to the phase split circuit 100 of FIG. 3 except for the cross-coupled latch 180c. For example, the cross-coupled latch 180c may be connected between the fifth node N5 and the sixth node N6. The cross-coupled latch 180c may store values of the first clock signal CK1 and the second clock signal CK2.

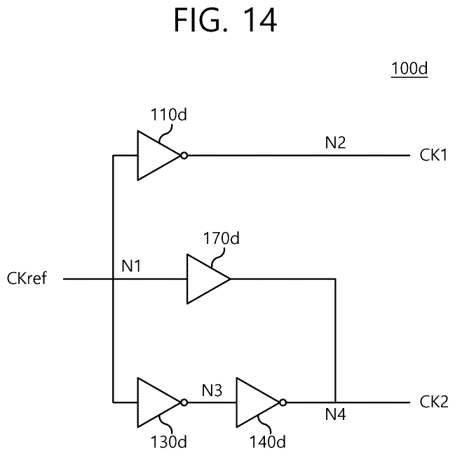

FIGS. 14 to 17 are diagrams illustrating examples of the phase split circuit of FIG. 2 according to some example embodiments. Referring to FIGS. 14 to 17, a phase split circuit may receive a reference clock signal CKref and output a first clock signal CK1 and a second clock signal CK2. The first clock signal CK1 may have a complementary phase with the reference clock signal CKref. The second clock signal CK2 may have the same phase with the reference clock signal CKref.

According to some example embodiments, the phase split circuit may output the first clock signal CK1 through at least an odd path. The phase split circuit may output the second clock signal CK2 through at least an even path. A signal passing through inverters of the even path may be phase-interpolated with a signal passing through a buffer, thereby improving a process variation of the phase split circuit.

Referring to FIG. 14, in some example embodiments, in a phase split circuit 100d, the reference clock signal CKref may be inverted through a first delay path including a first inverter 110d connected between a first node N1 and a second node N2 and an inverted signal of the reference clock signal CKref may be output as a first clock signal CK1. The reference clock signal CKref may be transmitted or sent through a second delay path including a buffer 170d connected between the first node N1 and a fourth node N4. In addition, in some example embodiments, the reference clock signal CKref may be transmitted or sent through a third delay path including a third inverter 130d and a fourth inverter 140d connected between the first node N1 and the fourth node N4. A signal passing through the second delay path and a signal passing through the third delay path may be combined and a combined signal may be output as a second clock signal CK2. The second clock signal CK2 may have the duty variation improved by the buffer 170d.

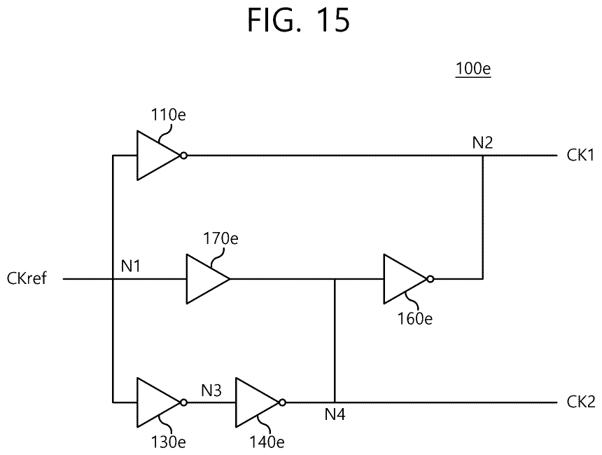

Referring to FIG. 15, in some example embodiments, in a phase split circuit 100e, the reference clock signal CKref may be inverted and transmitted or sent through a first delay path including a first inverter 110e connected between a first node N1 and a second node N2. In addition, in some example embodiments the reference clock signal CKref may be transmitted or sent through a second delay path including a buffer 170e and a sixth inverter 160e connected between the first node N1 and the second node N2. A signal passing through the first delay path and a signal passing through the second delay path may be combined at the second node N2 and a combined signal may be output as the first clock signal CK1. The first clock signal CK1 may have the duty variation improved through the buffer 170e.

The reference clock signal CKref may be transmitted or sent through a third delay path including the buffer 170e connected between the first node N1 and a fourth node N4. In addition, in some example embodiments, the reference clock signal CKref may be transmitted or sent through a fourth delay path including a third inverter 130e and a fourth inverter 140e connected between the first node N1 and the fourth node N4. A signal passing through the third delay path and a signal passing through the fourth delay path may be combined and a combined signal may be output as a second clock signal CK2. The second clock signal CK2 may have the duty variation improved by the buffer 170e.

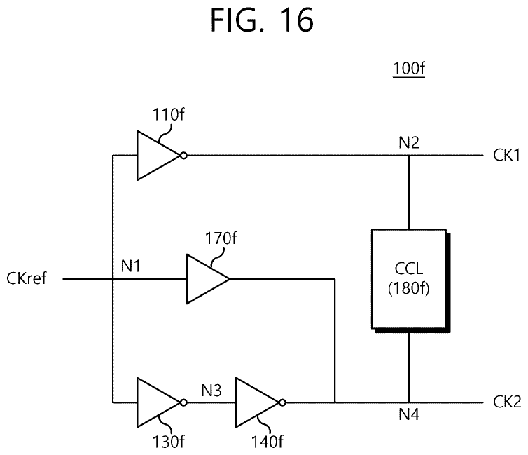

Referring to FIG. 16, in some example embodiments, a phase split circuit 100f may include a cross-coupled latch 180f. The phase split circuit 100f may be identical to the phase split circuit 100d of FIG. 14 except for the cross-coupled latch 180f. For example, the cross-coupled latch 180f may be connected between the second node N2 and the fourth node N4. The cross-coupled latch 180f may store values of the first clock signal CK1 and the second clock signal CK2.

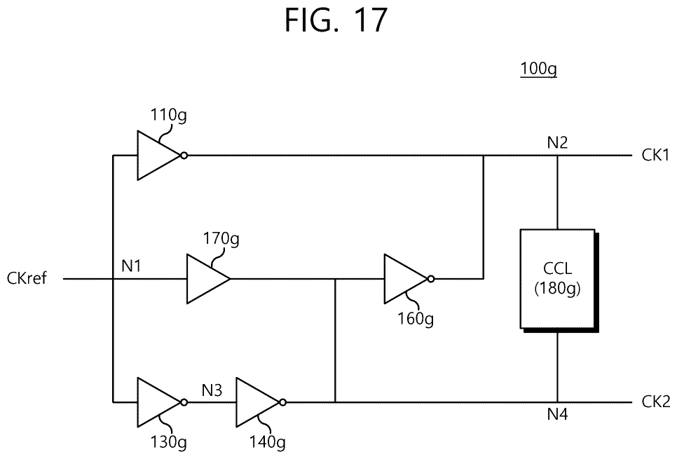

Referring to FIG. 17, in some example embodiments, a phase split circuit 100g may include the cross-coupled latch 180g. The phase split circuit 100g may be identical to the phase split circuit 100e of FIG. 15 except for the cross-coupled latch 180g. For example, the cross-coupled latch 180g may be connected between the second node N2 and the fourth node N4. The cross-coupled latch 180g may store values of the first clock signal CK1 and the second clock signal CK2.

According to some example embodiments of the present inventive concepts, it may be possible to provide complementary clock signals having uniform process variations in the phase split circuit.

According to some example embodiments of the present inventive concepts, it may be possible to perform a stable data read operation based on complementary clock signals having uniform process variations.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. A memory device, comprising:
a memory cell array including a plurality of memory cells;
an input/output circuit configured to input or output data to or from the plurality of memory cells; and
a phase split circuit configured to generate a first clock signal and a second clock signal used in the input/output circuit during an output operation of the data,
the phase split circuit including,
a first delay path including an even number of inverters included in a first inverter group, the first delay path configured to output a first delay signal when a reference clock signal passes through the first inverter group;
a second delay path including an even number of inverters included in a second inverter group, the second delay path configured to output a second delay signal when the reference clock signal passes through the second inverter group;
a first output terminal configured to phase-interpolate the first delay signal and the second delay signal to output the first clock signal;
a third delay path including an odd number of inverters included in a third inverter group and at least one buffer, the third delay path configured to output a third delay signal when the reference clock signal passes through the third inverter group and the at least one buffer;
a fourth delay path including an odd number of inverters included in a fourth inverter group, the fourth delay path configured to output a fourth delay signal when the reference clock signal passes through the fourth inverter group; and
a second output terminal configured to combine the third delay signal and the fourth delay signal to output the second clock signal complementary to the first clock signal.

2. The memory device of claim 1, wherein the even number of inverters included in the second inverter group is an integer multiple of the even number of inverters included in the first inverter group.

3. The memory device of claim 1, wherein
the first clock signal is configured to have a same phase as the reference clock signal, and
the second clock signal is configured to have a complementary phase to the reference clock signal.

4. The memory device of claim 1, wherein the third inverter group is configured to include an odd number of inverters among the first inverter group.

5. The memory device of claim 1, wherein the fourth inverter group is configured to include an odd number of inverters among the second inverter group.

6. The memory device of claim 1, wherein the odd number of inverters included in the fourth inverter group is greater than the odd number of inverters included in the third inverter group.

7. The memory device of claim 1, wherein a number of the at least one buffer is determined based on a difference between the odd number of inverters included in the third inverter group and the odd number of inverters included in the fourth inverter group.

8. The memory device of claim 1, wherein the input/output circuit is configured to generate the reference clock signal internally or generate the reference clock signal based on an external clock signal received from an external device.

9. A phase split circuit, comprising:
a first delay path including an even number of inverters included in a first inverter group, the first delay path configured to output a first delay signal when a reference clock signal passes through the first inverter group;
a second delay path including an even number of inverters included in a second inverter group, the second delay path configured to output a second delay signal when the reference clock signal passes through the second inverter group;
a first output terminal configured to phase-interpolate the first delay signal and the second delay signal to output a first clock signal having a same phase as the reference clock signal;
a third delay path including an odd number of inverters included in a third inverter group and at least one buffer, the third delay path configured to output a third delay signal when the reference clock signal passes through the third inverter group and the at least one buffer;
a fourth delay path including an odd number of inverters included in a fourth inverter group, the fourth delay path configured to output a fourth delay signal when the reference clock signal passes through the fourth inverter group; and
a second output terminal configured to combine the third delay signal and the fourth delay signal to output a second clock signal complementary to the first clock signal.

10. The phase split circuit of claim 9, wherein the third inverter group is configured to include an odd number of inverters among the first inverter group.

11. The phase split circuit of claim 9, wherein the fourth inverter group is configured to include an odd number of inverters among the second inverter group.

12. The phase split circuit of claim 9, wherein the odd number of inverters included in the fourth inverter group is greater than the odd number of inverters included in the third inverter group.

13. The phase split circuit of claim 9, wherein a number of the at least one buffer is determined based on a difference between the odd number of inverters included in the third inverter group and the odd number of inverters included in the fourth inverter group.

14. The phase split circuit of claim 9, wherein the at least one buffer is configured to offset a process variation corresponding to a portion of inverters among the fourth inverter group.

15. The phase split circuit of claim 9, wherein the even number of inverters included in the second inverter group is an integer multiple of the even number of inverters included in the first inverter group.

16. A phase split circuit, comprising:
a first delay path including an even number of inverters connected in series between an input terminal and a first output terminal;
a second delay path including an even number of inverters connected in series between the input terminal and the first output terminal, the second delay path configured to be connected in parallel to the first delay path and the first output terminal;
a third delay path including one inverter and at least one buffer connected in series between the input terminal and a second output terminal; and
a fourth delay path including an odd number of inverters connected in series between the input terminal and the second output terminal.

17. The phase split circuit of claim 16, wherein the first output terminal is configured to phase-interpolate a first delay signal output from the first delay path and a second delay signal output from the second delay path to generate a first clock signal.

18. The phase split circuit of claim 16, wherein the second output terminal is configured to combine a third delay signal output from the third delay path and a fourth delay signal output from the fourth delay path to generate a second clock signal.

19. The phase split circuit of claim 16, wherein the one inverter included in the third delay path is configured to be included as part of the first delay path.

20. The phase split circuit of claim 16, wherein the odd number of inverters included in the fourth delay path is configured to be included as part of the second delay path.
